(19) United States
(12) Patent Application Publication
(10) Pub. No.: US 2025/0287745 A1
(43) Pub. Date: Sep. 11, 2025

(54) Passive Stereoscopic Led Display Modules Having Optically Isolated Light Emitters

(71) Applicant: Liminal Space, Inc., Los Angeles, CA (US)

(72) Inventor: Nathaniel Huber, Hollywood, CA (US)

(21) Appl. No.: 18/604,368

(22) Filed: Mar. 13, 2024

Related U.S. Application Data
(60) Provisional application No. 63/563,362, filed on Mar. 9, 2024.

(51) Int. Cl. H01L 33/58; H01L 25/075; H04N 13/32

(52) U.S. Cl. CPC H10H 20/855; H01L 25/0753; H04N 13/32; H10H 20/0363

(57) ABSTRACT

The inventive subject matter provides apparatus and methods in which light emitters/light emitter packages are optically isolated from each other by a high opacity filler, which extends up above the tops of the polarizers, and in some cases covering portions of the top surfaces of the polarizers.

### PRIORITY

This application claims priority to U.S. provisional application Ser. No. 63/563,362 filed Mar. 10, 2024, which is incorporated herein by reference in its entirety. Where a definition or use of a term in the provisional is inconsistent or contrary to the definition of that term provided herein, the definition or use of that term provided herein is deemed to be controlling.

### FIELD OF THE INVENTION

The present invention generally relates to passive polarized three-dimensional (3D) stereoscopic light emitting diode (LED) display modules and systems.

### BACKGROUND

In a physical world viewing experience, each eye provides a slightly different image to the brain. Stereoscopic display systems attempt to recreate that visual experience using polarizers that present different views to each eye of a viewer. The viewer is able to see the two views by looking through two corresponding polarizers in the form of glasses or any other form of eye wearables such as contact lenses which transmit the disparate views to the correct eyes.

Earlier attempts to recreate a real world visual 3D experience employed an apparatus similar to corrective eyewear, comprising lenses of different colors. A monitor or projector projected two views on one screen, with each view being color coded so as to be complementary to one eyewear lens or the other. The use of color to segregate viewing channels would often lead to headaches for the viewers.

Recent 3D designs focus on creating a 3D viewing experience within a traditional movie theater environment, using devices centering around a display on a lenticular screen constructed of fabric. However, limited stereoscopic viewing advancements have occurred outside the movie theater environment, including on billboards and other public media/advertising delivery devices. In general, it would be desirable to provide a 3D viewing experience using a wider range of devices, billboards, LED movie theater screens, stadium jumbotrons, and/or other LED display devices.

### SUMMARY OF THE INVENTION

The inventive subject matter provides apparatus, systems, and methods in which light emitters and the attached polarizers to the light emitters are optically isolated from each other by a high opacity filler that extends up and over the top edges (perimeter) of the polarizers, resulting in improved optical isolation and image resolution. Typically, a low opacity protective covering is placed over the polarizers and high opacity filler.

In preferred embodiments, individual pixels perceived by a viewer are associated with sets of light emitters. As used herein, each set of light emitters can alternatively be only a single emitter, multiple emitters, or light emitter packages. Light emitters are preferably light emitting diodes (LEDs). Where a set of light emitters has only a single emitter, the emitter is advantageously configured to selectively emit multiple colors. Where a set of light emitters has multiple emitters, each of the emitters preferably emits a different color. In light emitter packages, the LED or other light emitters are contained within a defined structure. Various types of light emitter packages are contemplated herein, including but not limited to the following classifications of packages, such as glass on board (GOB), chip on board (COB), and surface mount device (SMD).

Extension of the high opacity filler over the top edges of the polarizers does reduce the total amount of light exiting the polarizers, and as such would be completely non-obvious to one of ordinary skill. Nevertheless, the current applicant has discovered that doing so provides significantly better optical isolation and image fidelity.

In another aspect of the inventive subject matter, the polarizers can be sloped, such that the high opacity filler is wider (horizontally) at the tops of the polarizers than at the bottoms. Here again one of ordinary skill would not think to adopt that practice since doing so narrows the polarizer top surface through which the polarized light can escape.

All types of polarizers are contemplated, including linear (left and right) polarizers, and circular (left and right) polarizers Where the polarizer is a circular polarizer, comprising a quarter wave plate disposed over a linear polarizer, the quarter wave plate might or might not be sloped, but is preferably narrower (horizontally) than the linear polarizer below it. This size difference allows the high opacity filler to be thicker at the top of the polarizer further improving its capability of absorbing unpolarized light.

Sets of light emitters or light emitter packages, along with their corresponding polarizers, high opacity filler and low opacity coatings, are preferably matrixed in a module, in a checkerboard or other desired arrangement. Modules can contain any suitable number of sets of light emitters, or light emitter packages, and attached polarizers, including for example 20, 64, 100, or even 1000 or more sets of light emitters or light emitter packages. Hundreds, thousands, even tens of thousands of modules can be arranged in a display.

Various resources, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1 is a prior art vertical cross-section of a LED module comprising sets of light emitters mounted on a substrate.

FIG. 2 is a vertical cross-section of a LED module comprising first and second light emitter packages and their attached circular polarizers (left and right), mounted and electrically connected to a substrate, wherein the packages are optically separated by a high opacity filler extending above the tops of the polarizers, with a low opacity coating layered above the high opacity filler and exposed portions of the polarizers.

FIG. 3 is a vertical cross-section of a portion of a prior art module with two light emitter packages and attached circular polarizers (left and right), and wherein the light emitter packages are mounted and electrically connected on a PCB or other substrate.

FIG. 4 is a vertical cross-section of a portion of a module comprising first and second set of light emitter packages with corresponding sloped circular polarizers (left and right), where the quarter wave plates are smaller in dimension than the linear polarizers beneath them, and wherein the light emitter packages are electrically connected to or mounted on a PCB or other substrate. The quarter wave plate is noticeably smaller in horizontal dimension than the linear polarizer beneath it.

FIG. 5 is a vertical cross-section of a portion of a module comprising first and second light emitter packages with a diffuser beneath the corresponding circular polarizers (left and right), and wherein the light emitter packages are electrically connected to or mounted on a PCB or other substrate.

FIG. 6 is a vertical cross-section of a portion of a module comprising first and second set of light emitter packages, with corresponding circular polarizers (left and right), wherein the light emitter packages are electrically connected to or mounted on a PCB or other substrate, and optically separated by a high opacity filler extending past the tops of the polarizers. A low opacity coating is layered above the high opacity filler and exposed polarizers.

FIG. 7 is a vertical cross-section of a portion of a module comprising first and second light emitter packages with corresponding circular polarizers (left and right), wherein the light emitter packages are electrically connected to or mounted on a PCB or other substrate, and are optically separated by a high opacity filler extending past the tops of the polarizers. The high opacity filler extends over the top of the polarizers and occludes a portion of the exposed top edges of the polarizers. A low opacity coating is layered above the high opacity filler and exposed polarizers.

FIG. 8 is a close up of a portion of the module of FIG. 7.

FIG. 9 is similar to FIG. 7, except that there is a diffuser above the adhesive.

FIG. 10 is a top perspective view of a module comprising first and second light emitter packages with corresponding circular polarizers (left and right), electrically connected to or mounted on a PCB or other substrate, wherein the light emitter packages are optically separated by a high opacity filler extending over the tops of the polarizers so that it occludes edges of the polarizers, prior to the addition of the low opacity coating layer.

FIG. 11 is a vertical cross-section of a portion of a module comprising first and second light emitter packages with corresponding circular polarizers (left and right), wherein the quarter wave plates of the circular polarizers are noticeably narrower in horizontal dimension than the linear polarizers beneath them, and wherein the light emitter packages are electrically connected to or mounted on a PCB or other substrate. The light emitter packages are optically separated by a high opacity filler that extends over the top edges of the polarizers, which occludes a portion of the exposed top edges of the polarizers. A low opacity coating is layered above the high opacity filler and exposed polarizers. The horizontal extent of the high opacity filler is greater (wider) at the top of the polarizers than between the light emitter packages beneath them, which increases the amount of light absorbed from the light emitters.

FIG. 12 is a vertical cross-section of a module comprising first and second light emitter packages with corresponding circular polarizers (left and right), wherein the quarter wave plates are narrower in horizontal dimension than the linear polarizers beneath them, and the light emitter packages are electrically connected to or mounted on a PCB or other substrate, and are optically separated by a high opacity filler extending to the tops of the quarter wave plates (QWP), with a low opacity coating layered above the high opacity filler and the exposed polarizers/quarter wave plates.

### DETAILED DESCRIPTION

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

The present designs are useful in overcoming issues with previous designs, by providing modules that include multiple light emitter/polarizer assemblies, bonded together by one or more high opacity fillers. To improve optical isolation and image fidelity, the high opacity filler extends up and over the top edges of the polarizers, and/or is wider (horizontally) at the tops of the polarizers than at the bottoms. Multiple modules can be readily combined into stereoscopic display systems.

All types of encapsulated LED packages or unencapsulated light emitters, can be employed in the completed designs. Contemplated light emitters include RGB semi-conductors or diodes, RGBY semi-conductors or diodes, RGBC (Cyan) semi-conductors or diodes, RGB plus infrared semi-conductors or diodes, digital RGB, surface-mounted device LED package (SMDs), chip on board (COB) LED packages, glass on board (GOB) LED packages, quantum dot LEDs, and micro LEDs.

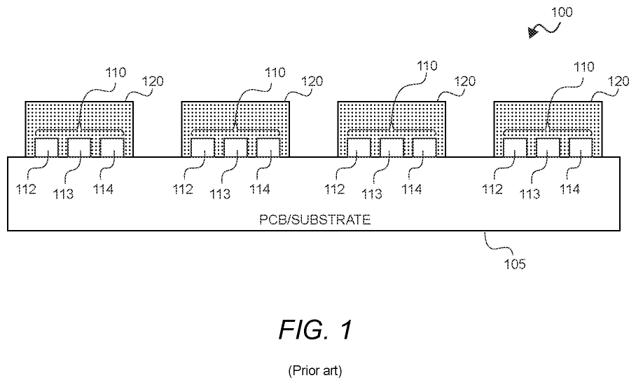

FIG. 1 is a prior art vertical cross-section of a portion of a module 100 comprising sets of light emitters 110 mounted on a substrate 105. Each of the sets of light emitters 110 includes a red light emitting semi-conductor or diode 112, a green light emitting semi-conductor or diode 113, and a blue light emitting semi-conductor or diode 114. There is a coating 120 around each of the sets of light emitters 110.

Data/power lines (not shown) are connected to each of the light emitters. The data and power connections are well-known to one of ordinary skill, and can be embedded within the substrate. The data and power can use the same or different connections.

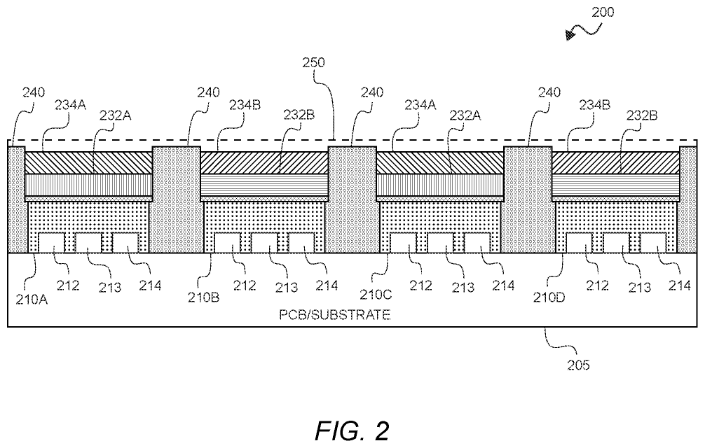

FIG. 2 is a vertical cross-section of a LED module 200 comprising four light emitter packages 210A, 210B, 210C, 210D mounted on a substrate 205. Each of the light emitter packages 210A, 210B, 210C, 210D includes a red light emitting semi-conductor or diode 212, a green light emitting semi-conductor or diode 213, and a blue light emitting semi-conductor or diode 214. Data/power lines (not shown) connect to the light emitters through the substrate. The data and power connections are well-known to one of ordinary skill, and can be embedded within the substrate.

Above the first and third light emitter packages 210A, 210C is an adhesive 220, and a left circular polarizer comprising a first linear polarizer 232A and a first quarter wave plate (QWP) 234A. Above the second and fourth light emitter packages 210B 210D is adhesive 220, and a right circular polarizer comprising a second linear polarizer 232B and a second quarter wave plate (QWP) 234B.

Other embodiments of the apparatus may just use linear polarizers (left and right) instead of circular polarizers (left and right). Each of the light emitter packages 210A, 210B, 210C, 210D and associated polarizers are optically separated by a high opacity filler 240 extending up slightly past the tops of the circular polarizers 230A, 230B. A low opacity coating 250 is layered above the high opacity filler 240 and the exposed polarizers 230A, 230B.

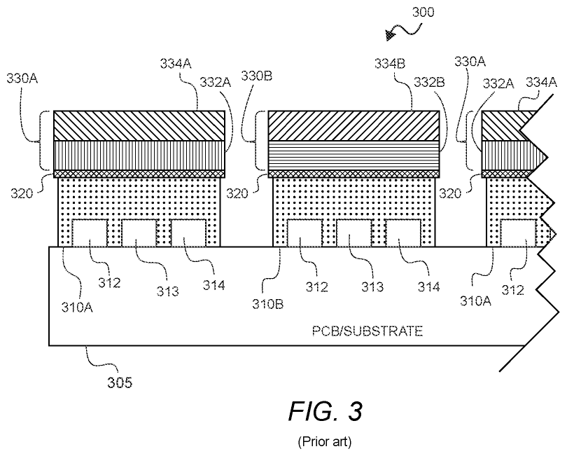

FIG. 3 is a vertical cross-section of a portion of a prior art module 300 comprising first and second sets of different colored light emitter packages 310A, 310B mounted on a substrate 305. Each of the light emitter packages 310A, 310B includes a red light emitting semi-conductor or diode 312, a green light emitting semi-conductor or diode 313, and a blue light emitting semi-conductor or diode 314. Data/power lines (not shown) are embedded in the PCB and are electrically connected to each light emitter package 310A, 310B and provide data and power to the light emitting semi-conductors or diodes 312, 313, 314. Above light emitter packages 310A is an adhesive 320, and a left circular polarizer 330A comprising first 332A linear polarizer and quarter wave plate (QWP) 334A. Above light emitter package 310B is an adhesive 320, and a right circular polarizer 330B, 330A comprising first 332BA linear polarizer and quarter wave plate (QWP) 334B.

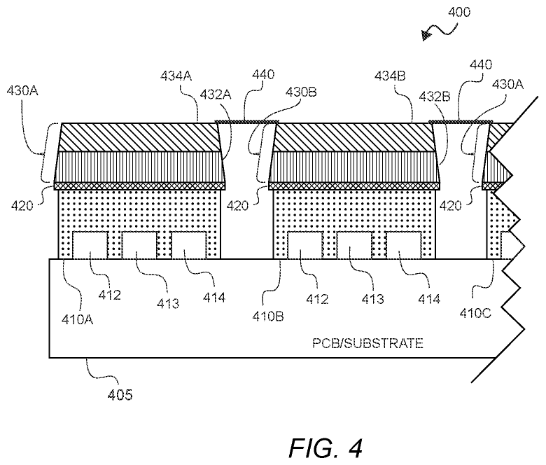

FIG. 4 is a vertical cross-section of a module 400 comprising first, second, and third light emitter packages 410A, 410B, 410C mounted on a substrate 405. Each of the light emitter packages 410A, 410B, 410C includes a red light emitting semi-conductor or diode 412, a green light emitting semi-conductor or diode 413, and a blue light emitting semi-conductor or diode 414. Data/power lines (not shown) are embedded in the PCB and are electrically connected to each light emitter package 410A, 410B, 410C and provide data and power to the light emitting semi-conductors or diodes 412, 413, 414. Above the first and third light emitter packages 410A, 410C are an adhesive 420, and a left circular polarizer 430A comprising first linear polarizer 432A and first quarter wave plate (QWP) 434A. Above the second light emitter package 410B is the adhesive 420, and right circular polarizer 430B comprising second linear polarizer 432B and second quarter wave plate (QWP) 434B.

In this embodiment the sides of circular polarizers 430A, 430B are slanted, such that the quarter wave plates 434A, 434B are narrower (horizontally) than the linear polarizers 432A, 434B, respectively beneath them. Optional high opacity filler 440 extends above the top of the circular polarizers 430A, 430B. FIG. 4 should be interpreted such that optional high opacity filler 440 can extend even around the edges of the circular polarizers 430A, 430B. A low opacity coating (not shown) is above the exposed circular polarizers 430A, 430B and high opacity filler 440.

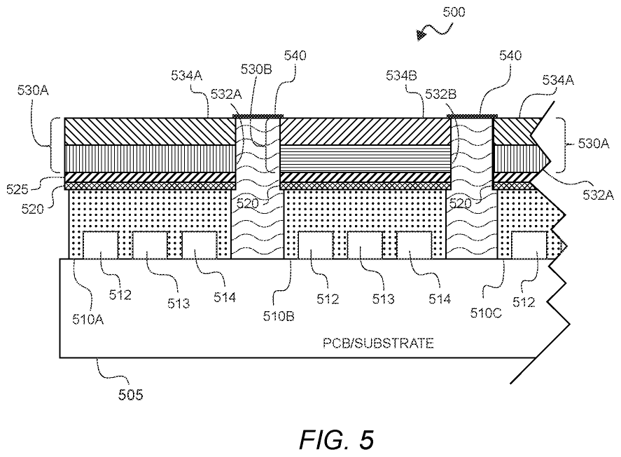

FIG. 5 is a vertical cross-section image of a portion of module 500 comprising first, second, and third light emitter packages 510A, 510B, 510C mounted on a substrate 505. Each of the light packages 510A, 510B, 510C includes a red light emitting semi-conductor or diode 512, a green light emitting semi-conductor or diode 513, and a blue light emitting semi-conductor or diode 514. Data/power lines (not shown) are embedded in the PCB and are electrically connected to each light emitter package 510A, 510B, 510C and provide data and power to the light emitting semi-conductors or diodes 512, 513, 514. Above the first and third light emitter packages 510A, 510C are an adhesive 520, a diffuser 525, and a left circular polarizer 530A comprising first linear polarizer 532A and first quarter wave plate (QWP) 534A. Above the second light emitter package 510B is the adhesive 520, a diffuser 525, and a right circular polarizer 530B comprising second linear polarizer 532B and second quarter wave plate (QWP) 534B.

In this embodiment the sides of circular polarizers 530A, 530B are vertical. Optional high opacity filler 540 extends above the top of the circular polarizers 530A, 530B. FIG. 5 should be interpreted such that optional high opacity filler 540 can extend even around the edges of the circular polarizers 530A, 530B. A low opacity coating (not shown) is above the exposed circular polarizers 530A, 530B and high opacity filler 540.

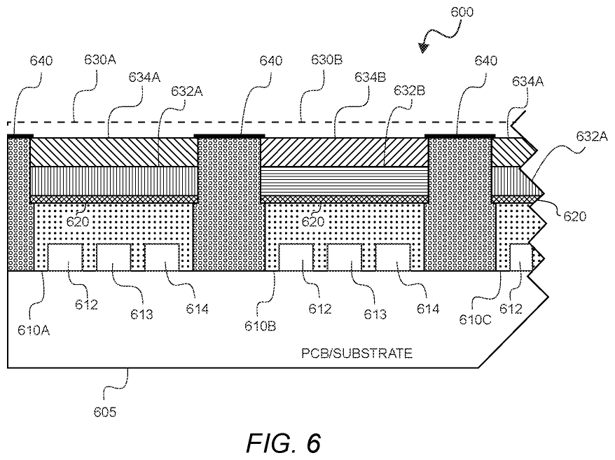

FIG. 6 is a vertical cross-section of a portion of module 600 comprising first, second, and third light emitter packages 610A, 610B, 610C mounted on a substrate 605. Each of the light packages 610A, 610B, 610C includes a red light emitting semi-conductor or diode 612, a green light emitting semi-conductor or diode 613, and a blue light emitting semi-conductor or diode 614. Data/power lines (not shown) are embedded in the PCB and are electrically connected to each light emitter package 610A, 610B, 610C and provide data and power to the light emitting semi-conductors or diodes 612, 613, 614. Above the first and third light emitter packages 610A, 610C are an adhesive 620, and a left circular polarizer 630A comprising first linear polarizer 632A and first quarter wave plate (QWP) 634A. Above the second light emitter package 610B is the adhesive 620, and a right circular polarizer 630B comprising second linear polarizer 632B and second quarter wave plate (QWP) 634B. A low opacity coating 650 is layered above the high opacity filler 640 and the exposed polarizers 630A, 630B.

In this embodiment the sides of circular polarizers 630A, 630B are vertical, and there are no diffusers. High opacity filler 640 extends above the tops of the circular polarizers 630A, 630B.

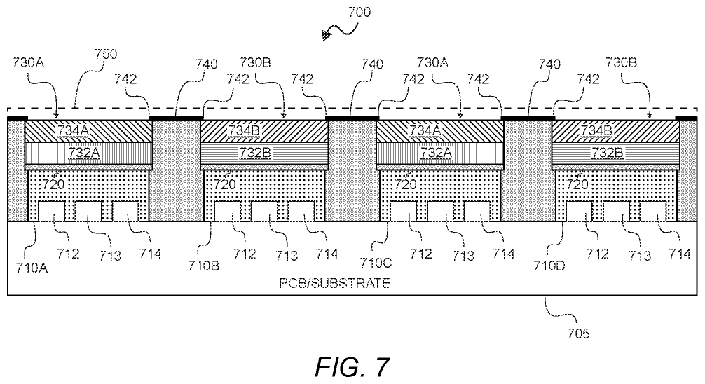

FIG. 7 is a vertical cross-section of a portion of module 700 comprising first, second, and third light emitter packages 710A, 710B, 710C mounted on a substrate 705. Each of the light packages 710A, 710B, 710C includes a red light emitting semi-conductor or diode 712, a green light emitting semi-conductor or diode 713, and a blue light emitting semi-conductor or diode 714. Data/power lines (not shown) are embedded in the PCB and are electrically connected to each light emitter package 710A, 710B, 710C and provide data and power to the light emitting semi-conductors or diodes 712, 713, 714. Above the first and third light emitter packages 710A, 710C are an adhesive 720, and a left circular polarizer 730A comprising first linear polarizer 732A and first quarter wave plate (QWP) 734A. Above the second light emitter package 710B is the adhesive 720, and a right circular polarizer 730B comprising second linear polarizer 732B and second quarter wave plate (QWP) 734B. A low opacity coating 750 is layered above the high opacity filler 740 and the exposed polarizers 730A, 730B.

In this embodiment the sides of circular polarizers 730A, 730B are vertical, and there are no diffusers. A small portion 742 of the high opacity filler 740 extends over the top edges of the polarizers 730A, 730B and occludes a portion the outer edges of the polarizers 730A, 730B. A low opacity coating 750 is layered above the high opacity filler 740, 742 and the exposed polarizers 730A, 730B.

FIG. 8 is a close up of a portion of the module of FIG. 7.

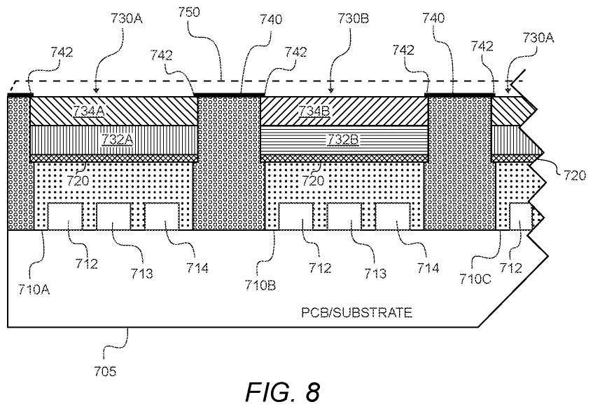

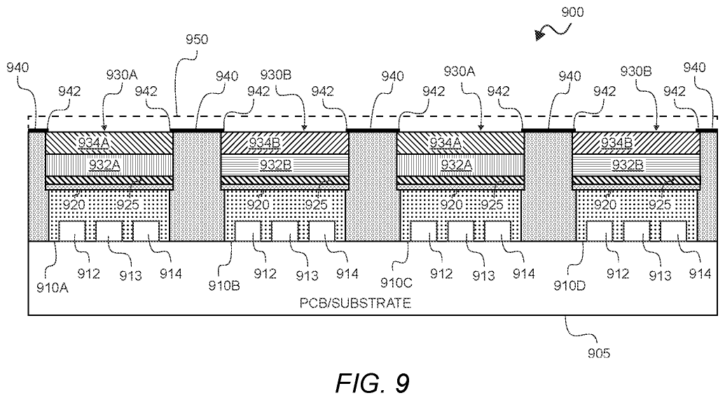

FIG. 9 is a vertical cross-section of a portion of module 900 comprising first, second, and third light emitter packages 910A, 910B, 910C mounted on a substrate 905. Each of the light packages 910A, 910B, 910C includes a red light emitting semi-conductor or diode 912, a green light emitting semi-conductor or diode 913, and a blue light emitting semi-conductor or diode 914. Data/power lines (not shown) are embedded in the PCB and are electrically connected to each light emitter package 910A, 910B, 910C and provide data and power to the light emitting semi-conductors or diodes 912, 913, 914. Above the first and third light emitter packages 910A, 910C are an adhesive 920, a diffuser 925, and a left circular polarizer 930A comprising first linear polarizer 932A and first quarter wave plate (QWP) 934A. Above the second light emitter package 910B is the adhesive 920, a diffuser 925, and a right circular polarizer 930B comprising second linear polarizer 932B and second quarter wave plate (QWP) 934B. A low opacity coating 950 is layered above the high opacity filler 940 and the exposed polarizers 930A, 930B.

In this embodiment the sides of circular polarizers 930A, 930B are vertical. A small portion 942 of the high opacity filler 940 extends over the top edges of the polarizers 930A, 930B and occludes a portion the outer edges of the polarizers 930A, 930B. A low opacity coating 950 is layered above the high opacity filler 940, 942 and the exposed polarizers 930A, 930B.

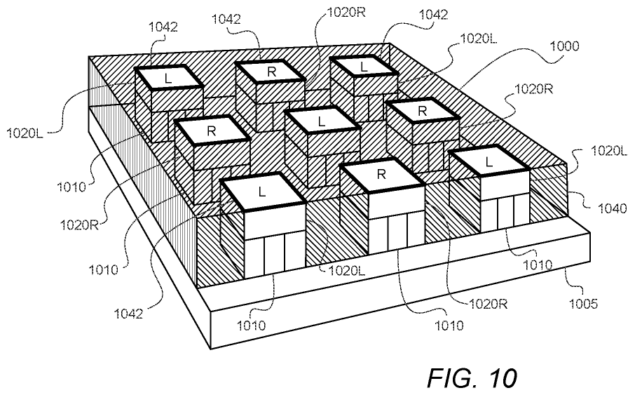

FIG. 10 is a top perspective view of a module 1000 comprising nine assemblies 1100 of light emitter packages 1010 and associated polarizers 1020L, 1020R, arranged in a checkerboard pattern, prior to addition of a protective a low opacity coating. High opacity filler 1040 extends between the of light emitter packages 1010 and associated polarizers 1020L, 1020R, and portions 1042 of the high opacity filler 1042 extend over the edges of the polarizers 1020L, 1020R. The nine assemblies are disposed on top of substrate 1005.

Each of high opacity filler 240, 440, 540, 640, 740, 940, 1040 extends between adjacent sets of light emitters, and up past the top of the corresponding quarter wave plate or other polarizers (e.g., 230A, 230B, 730A, 730B, 940A, 940B). Extending the high opacity filler from the substrate to the height that is at least to the top of the quarter wave plate reduces the amount of non-linearly polarized light from passing through the quarter wave plate.

Furthermore, extending the high opacity filler from the substrate up past the top of the polarizer even further reduces the unpolarized light from escaping the leading edges of the polarizing material or lens. This reduces the cross-talk of the adjacent light emitters/light emitter packages, and increases the stereo contrast ratio. A high stereo contrast ratio relates directly to a high resolution stereoscopic LED display. The stereo contrast ratio is established by dividing the luminance value of a given light emitter/package during the polarized cancelled light or dark start by the uncancelled light or light state of the polarized light emitter/package (Light State÷Dark State=Stereo Contrast: 1).

Still further, the high opacity filler 742, 942, 1042 extends up over the edges of the polarizers to occlude a small portion of the surface of the quarter wave plate or other polarizer.

The Applicant's theory is that the outer perimeter of the top surface of a polarizer material or lens will tend to have lower levels of polarization than its inner sections not directly next to the edge. The high opacity filler is thus not able to absorb all of the refracted unpolarized light that escapes the sides of the polarizer material or lens. The outer edges of the polarizer material lose the ability to effectively polarize light during the process of producing the polarizer materials that are attached to the surface of the light emitters. By allowing the unpolarized perimeter light to escape the top edges of the polarizer greatly reduces the effectiveness of the polarized light emitters. Therefore, allowing the high-opacity filler to extend over the top of the polarizer surface, and preferably generating a lip that extends around the edges of the polarizer, over a small portion of the polarizer material or lens greatly increases the effectiveness of the polarized light emitted from the device.

In tests the inventor has seen a marked increase in stereo contrast ratios, up to 4 times that of a polarizer that doesn't have a high opacity filler lip extending over the edges of the surface of the polarizer material. In this way, at least 45% of light passing out of the device passes through a polarizer, more preferably at least 75% or even at least 90% of light passing out of the device passes through a polarizer. High opacity filler 240, 440, 540, 640, 740, 940, 1040 is preferably silicone or other resin, and is preferably made opaque by inclusion of graphene, black die, or acrylic pigments.

Low opacity coating 250, 650, 750, 950 is preferably substantially transparent, at least to visible light. Suitable materials for low opacity coating include a two-part, room temperature curing, or UV cured resin.

Optional diffusers 525. 925 can enhance the three-dimensional effect in at least two ways. First, without a diffuser, light from the light emitters can tend to “blow thru” polarizers, causing a ghosting effect that may detract from the viewing experience. Second, addition of a diffuser spreads out the light, creating a reduced lumens-per-square-millimeter value that enhances the polarization effect. In different contemplated embodiments, a diffuser can be placed above the polarizers to reduce glare and increase the effective viewing angle.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something designated from the group consisting of A, B, C . . . and N, the text should be interpreted as requiring only one element from the group, not A plus N, or B plus N, etc.

1. A LED (Light Emitting Diode) display module, comprising:
a substrate;
a matrix of at least first and second spaced apart sets of light emitters, electrically attached to the substrate, and extending above the substrate;
first and second polarizers disposed above the first and second sets of light emitters, respectively; wherein the polarity of the first polarizer is different from the second polarizer;
a composition extending between the first and second sets of light emitters, and disposed at a height that extends past the top of each of the first and second sets of polarizers; and
a low opacity coating disposed above the first and second polarizers and composition

2. The display module of claim 1, wherein the light emitters are contained in light emitter packages.

3. The display module of claim 1, wherein the composition extends over the top of the first and second polarizers such that it occludes at least 0.5% of the edge of the top surface of the first and second polarizers.

4. The display module of claim 1, wherein each of the first and second sets of light emitters emits at least three different colors.

5. The display module of claim 1, wherein each of the first and second sets of light emitters includes a single light emitting element addressable to produce a range of wavelengths between 400 and 750 nanometers.

6. The display module of claim 1, wherein each of the first and second sets of light emitters includes multiple light emitting elements that are collectively addressable to produce a range of wavelengths between 400 and 750 nanometers.

7. The display module of claim 1, further comprising first and second diffusers disposed under the first and second polarizers, respectively.

8. The display module of claim 7, wherein the composition is disposed about the first set of light emitters, the first diffuser, and the first polarizer such that such that at least a combined total of 45% intensity of light between 400 and 750 nanometers, which passes out of the matrix from the first set of light emitters, passes through the first polarizer.

9. The display module of claim 1, wherein each of the first and second sets of light emitters is distanced from the first and second polarizers, respectively.

10. The display module of claim 1, wherein the first and second polarizers polarize light in different circularly polarized directions, respectively.

11. The display module of claim 1, wherein the first and second polarizers polarize light in left and right directions, respectively.

12. The display module of claim 1, wherein the first polarizer is one of a total even number of left directional polarizers.

13. The display module of claim 1, wherein the first polarizer is one of a total odd number of left directional polarizers.

14. The display module of claim 1, wherein the first polarizer is one of a number left directional polarizers, and the second polarizer is one of a number right directional polarizers, and the left and right polarizers are arranged in a checkerboard pattern.

15. The display module of claim 1, wherein the first polarizer is one of a number left directional polarizers, and the second polarizer is one of a number right directional polarizers, and the left and right polarizers are arranged in alternating rows.

16. The display module of claim 1, wherein the first and second polarizers are included within a polarizing film.

17. The display module of claim 1, wherein the composition opacity comprises a resin.

18. The display module of claim 1, wherein the composition opacity transmits less than 80% of light transmitted by the low opacity coating of light between 400 and 750 nanometers, for total light intensity less than 20 lumens.

19. The display module of claim 1, wherein the composition opacity transmits less than 50% of light transmitted by the low opacity coating of light between 400 and 750 nanometers, for total light intensity less than 20 lumens.

20. The display module of claim 1, wherein the composition opacity transmits less than 20% of light transmitted by the low opacity coating of light between 400 and 750 nanometers, for total light intensity less than 20 lumens.

21. The display module of claim 1, wherein each of the first and second sets of light emitters is contained within a surface-mounted device LED package.

22. The display module of claim 1, wherein the matrix includes at least 100 of the sets of light emitters.

23. The display module of claim 1, wherein the matrix includes at least 1000 of the sets of light emitters.

24. The display module of claim 1, physically coupled with at least 99 other instances of the display module of claim 1.

25. The display module of claim 1, wherein the sets of light emitters produce infrared light.

26. A method of manufacturing a LED (Light Emitting Diode) display module, comprising:
depositing light emitter packages above a substrate;
depositing polarizers above the light emitter packages;
depositing a composition among the light emitter packages, up to and above the top of the polarizers;
depositing a low opacity material above the high opacity filler and exposed portions of the polarizers.

27. The method of claim 26, further comprising depositing the composition over portions of the top surfaces of the polarizers.
